(19) United States
(12) Patent Application Publication
(10) Pub. No.: US 2010/0176892 A1
(43) Pub. Date: Jul. 15, 2010

(54) Ultra Low Power Oscillator

(75) Inventors: Erik Jonathon Thompson, Phoenix, AZ (US); Gregory Lewis Dean, Phoenix, AZ (US); Jaswinder Jandu, Chandler, AZ (US); Richard Alexander Erhard, Tempe, AZ (US)

Correspondence Address: Stevens Law Group, 1754 Technology Drive, Suite #226, San Jose, CA, 95110, US

(73) Assignee: Validity Sensors, Inc., San Jose, CA (US)

(21) Appl. No.: 12/354,699

(22) Filed: Jan. 15, 2009

(51) Int. Cl. H03K 3/00

(52) U.S. Cl. 331/111

(57) ABSTRACT

A low power oscillator is disclosed in one embodiment of the invention as including a Schmitt trigger having an input, an output, and an input stage coupled to the input. The input stage may include multiple transistors connected in series between a power source and ground. A switch, controlled by the output of the Schmitt trigger, may be connected in series with the multiple transistors. The switch is configured to interrupt shoot-through current passing through the transistors when the transistors are turned on at the same time. In certain embodiments, the switch may reduce the shoot-through current by substantially half.

### BACKGROUND

This invention relates to oscillators for providing timing and clocking signals, and more particularly to apparatus and methods for significantly reducing the power consumed by oscillators for providing timing and clocking signals.

Power management is increasingly important in today's mobile electronic devices as greater reliance is placed on batteries and other mobile energy sources. This is true for devices such as portable computers, personal data assistants (PDAs), cell phones, gaming devices, navigation devices, information appliances, and the like. Furthermore, with the convergence of computing, communication, entertainment, and other applications in mobile electronic devices, power demands continue to increase at a rapid pace, with battery technology struggling to keep pace. At the same time, notwithstanding the additional features and capability that are provided in modern electronic devices, consumers still desire elegant, compact devices that are small enough to be slipped into a pocket or handbag.

Electronic or electro-mechanical oscillators are one of many components that consume significant amounts of power in electronic circuits. Oscillators of various types are required by many electronic circuits to provide timing and clocking signals. In certain cases, an oscillator may continue to operate even while other electronic components are temporarily shut down or put in standby or sleep mode to conserve power. This may create an undesirable power drain in devices that would otherwise be able to operate at very low power levels. Thus, it would be a significant advance in the art to reduce the power that is consumed by electronic or electro-mechanical oscillators.

FIG. 1A shows one example of a relaxation oscillator 10 to produce a square-wave output suitable for providing a clocking or timing signal. In this example, the relaxation oscillator 10 includes a Schmitt trigger 12, a capacitor 14, and a pair of current sources 16a, 16b. The current sources 16a, 16b may be coupled to switches 18a, 18b and may take turns charging and discharging the capacitor 14. More specifically, a first current source 16a may charge the capacitor 14 and a second current source 16b may discharge the capacitor 14. The output 20 from the Schmitt trigger 12 may determine which current source 16a, 16b is coupled to the capacitor 14 and therefore either charges or discharges the capacitor 14. An inverter 22 may ensure that when one switch 18a, 18b is closed, the other is open.

FIG. 1B shows the relationship between the input 24 and the output 20 of the Schmitt trigger 12. As shown, the output signal 26 is a square-wave signal suitable for providing a clocking or timing signal. The input signal 28 may be a saw-tooth wave that reflects the charging and discharging of the capacitor 14. As shown, the voltage of the input signal 28 may increase until an upper threshold 30a of the Schmitt trigger 12 is reached. At this point, the output of the Schmitt trigger 12 may change state, causing the circuit 10 to flip from one current source 16a to the other 16b and begin to discharge the capacitor 14.

When the voltage of the input signal 28 reaches a lower threshold 30b, the output signal 26 of the Schmitt trigger 12 may change state again, causing the current source 16a to begin to recharge the capacitor 14. The circuit 10 may continue to alternate between these two states to generate the illustrated signals 26, 28. The frequency of the oscillator 10 may depend on the magnitude of the current generated by the current sources 16a, 16b, the size of the capacitor 14, and the hysteresis characteristics of the Schmitt trigger 12.

As shown in FIG. 2A, conventional CMOS Schmitt triggers 12 typically include an input stage 40 with some combination of PMOS devices 42 and NMOS devices 44 stacked between a power source 46 and ground 48. Here, a pair of PMOS and NMOS devices 42, 44 is shown for illustration purposes. The CMOS devices 42, 44 may control the flow of electrical current between the power source 46 and ground 48.

As shown in FIG. 2B, for a relatively slow moving input signal 50, when the input 50 is at or near the upper or lower thresholds 30a, 30b of the Schmitt trigger 12, there is a period where both the PMOS and NMOS devices 42, 44 are turned on at the same time. During this period, electrical current is conducted from the power supply 46 to ground 48. This wasted current is typically referred to as “shoot-through” current 54 and is represented by the waveform 56 of FIG. 2B. Because the input voltage 50 is at or near the upper and lower thresholds 30a, 30b a significant portion of the time, the shoot-through current 54 is a substantial portion of the average current of the oscillator 10, as shown in FIG. 2C.

In view of the foregoing, what are needed are apparatus and methods for reducing the power consumed by electronic and electro-mechanical oscillators. In particular, apparatus and methods and needed to reduce wasted current, such as “shoot-through” current, in relaxation or other types of oscillators.

### BRIEF DESCRIPTION OF THE DRAWINGS

In order that the advantages of the invention will be readily understood, a more particular description of the invention briefly described above will be rendered by reference to specific examples illustrated in the appended drawings. Understanding that these drawings depict only typical examples of the invention and are not therefore to be considered limiting of its scope, the invention will be described and explained with additional specificity and detail through the use of the accompanying drawings, in which:

FIG. 1A is a high-level schematic diagram of one embodiment of a relaxation oscillator for producing a square-wave output;

FIG. 1B is a timing diagram showing the relationship between the input and output of the Schmitt trigger of FIG. 1A;

FIG. 2A is a high-level schematic diagram showing one embodiment of an input stage of a prior art Schmitt trigger;

FIGS. 2B and 2C are timing diagrams showing the “shoot-through” current for the prior art Schmitt trigger of FIG. 2A;

FIG. 3A is a high-level schematic diagram showing one embodiment of an input stage of a low power Schmitt trigger in accordance with the invention;

FIGS. 3B and 3C are timing diagrams showing the “shoot-through” current for the low power Schmitt trigger of FIG. 3A;

FIG. 4A is a high-level schematic diagram showing another embodiment of an input stage of a low power Schmitt trigger in accordance with the invention;

FIGS. 4B and 4C are timing diagrams showing the “shoot-through” current for the low power Schmitt trigger of FIG. 4A;

FIG. 5 is a schematic diagram of one embodiment of an RS latch, using Boolean logic gates, for implementing a Schmitt trigger in accordance with the invention; and

FIG. 6 is a schematic diagram of one embodiment of an RS latch, using transistors, for implementing a Schmitt trigger in accordance with the invention.

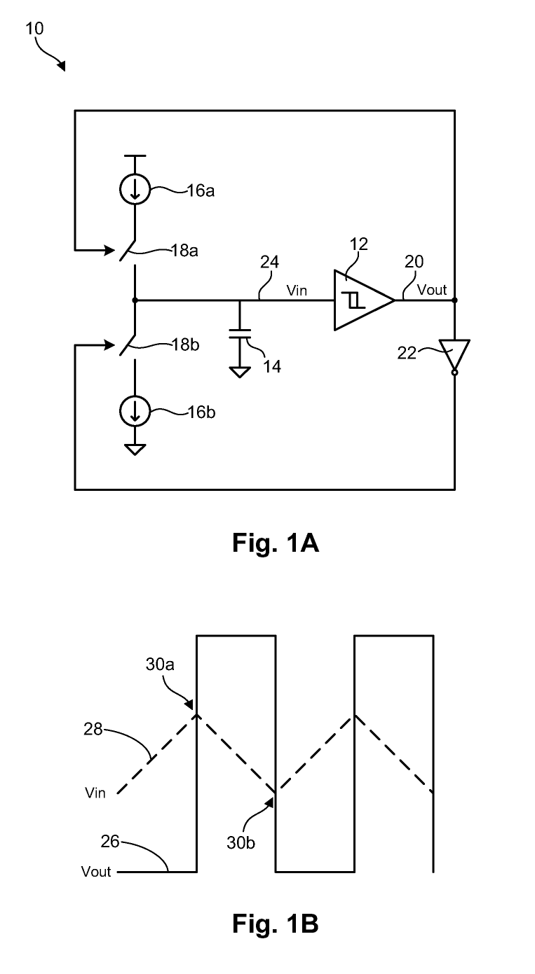

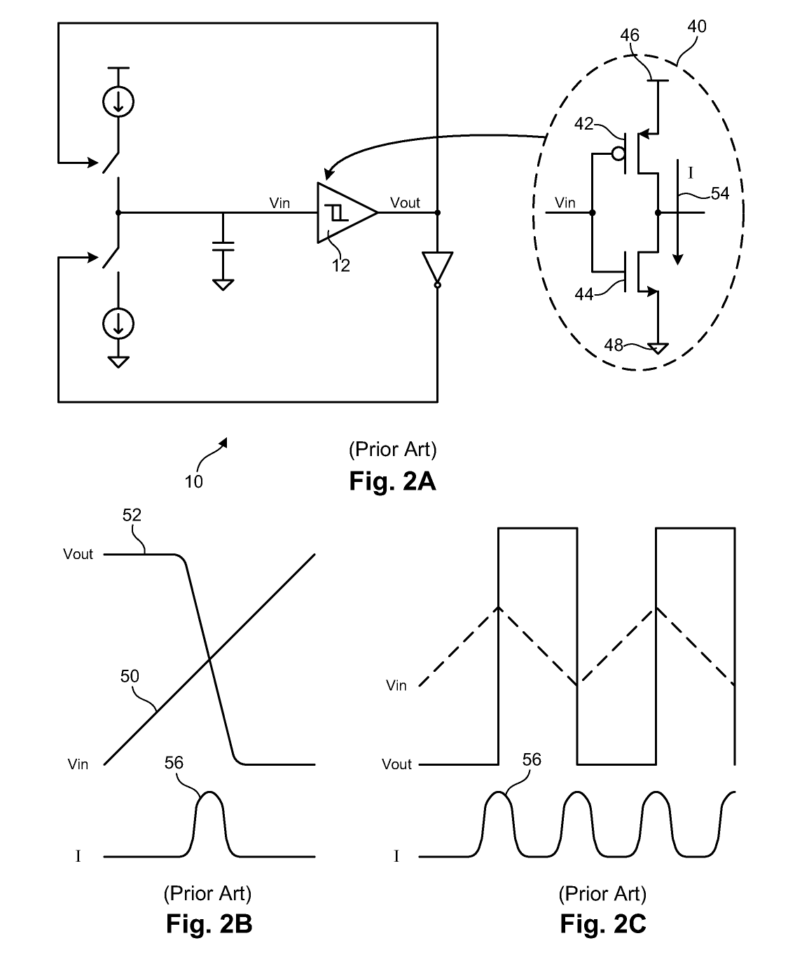

### DETAILED DESCRIPTION

The invention has been developed in response to the present state of the art and, in particular, in response to the problems and needs in the art that have not yet been fully solved by currently available oscillators. Accordingly, the invention has been developed to provide novel apparatus and methods for reducing oscillator power consumption. The features and advantages of the invention will become more fully apparent from the following description and appended claims and their equivalents, and also any subsequent claims or amendments presented, or may be learned by practice of the invention as set forth hereinafter.

Consistent with the foregoing, a low power oscillator is disclosed in one embodiment of the invention as including a Schmitt trigger having an input, an output, and an input stage coupled to the input. The input stage may include multiple transistors connected in series between a power source and ground. A switch, controlled by the output of the Schmitt trigger, may be connected in series with the multiple transistors. The switch is configured to interrupt shoot-through current passing through the transistors when the transistors are turned on at the same time. In certain embodiments, the switch may reduce the shoot-through current by substantially half.

In certain embodiments, the low power oscillator may further include a current source connected in series with the multiple transistors. This current source may limit the magnitude of the shoot-through current passing through the transistors.

In selected embodiments, the transistors may include one or more re-channel field-effect transistors (FETs) and one or more p-channel FETs. For example, the transistors may include one or more NMOS FETs and one or more PMOS FETs. Similarly, in selected embodiments, the switch may include one or more FETs. For example, the switch may include one or more PMOS or NMOS FETs. Likewise, in selected embodiments, the current source may include one or more FETs, such as one or more PMOS or NMOS FETs.

In another embodiment in accordance with the invention, a method for reducing the power consumed by an oscillator includes providing a Schmitt trigger having an input, an output, and an input stage coupled to the input. The input stage may include multiple transistors connected in series between a power source and ground. The method may further include interrupting, in response to feedback from the Schmitt trigger output, shoot-through current passing through the transistors when the FETs are turned on at the same time. In certain embodiments, the method may further include limiting the magnitude of the shoot-through current with a current source.

In yet another embodiment of the invention, a low power oscillator in accordance with the invention may include a Schmitt trigger having an input, an output, and an input stage coupled to the input. The input stage may include multiple field-effect transistors (FETs) connected in series between a power source and ground. A switch, controlled by the output of the Schmitt trigger, may be connected in series with the FETs. The switch may substantially reduce by half the shoot-through current passing through the FETs while they are simultaneously turned on. A current source is also connected in series with the FETs to limit the magnitude of the shoot-through current passing therethrough.

It will be readily understood that the components of the present invention, as generally described and illustrated in the Figures herein, could be arranged and designed in a wide variety of different configurations. Thus, the following more detailed description of the embodiments of apparatus and methods in accordance with the present invention, as represented in the Figures, is not intended to limit the scope of the invention, as claimed, but is merely representative of certain examples of presently contemplated embodiments in accordance with the invention. The presently described embodiments will be best understood by reference to the drawings, wherein like parts are designated by like numerals throughout.

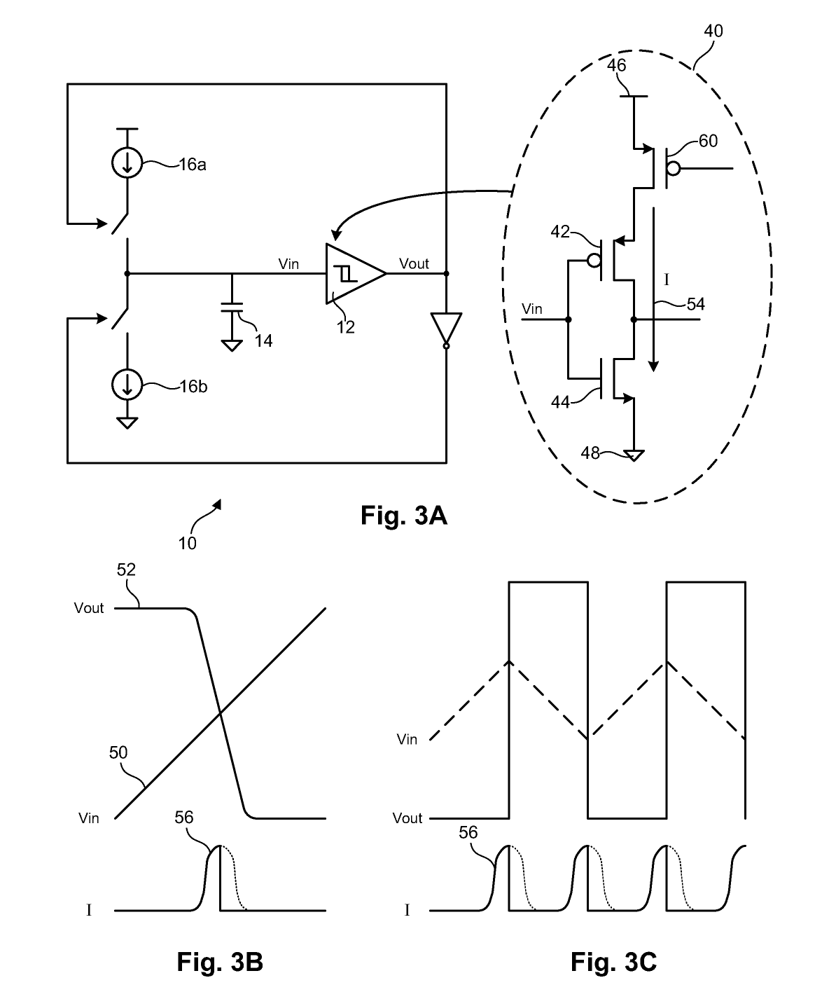

Referring to FIG. 3A, one embodiment of a relaxation oscillator 10 for producing a square-wave output is illustrated. In this example, the relaxation oscillator 10 includes a Schmitt trigger 12, a capacitor 14, and a pair of current sources 16a, 16b for charging and discharging the capacitor 14. The relaxation oscillator 10 is provided only by way of example and is not intended to be limiting. Indeed, the apparatus and methods disclosed herein may be used to reduce power consumption in a wide variety of different oscillator circuits and are not limited to the illustrated oscillator circuit 10.

As previously mentioned, conventional CMOS Schmitt triggers 12 may include an input stage 40 with some combination of PMOS devices 42 and NMOS devices 44 stacked between a power source 46 and ground 48. In this example, two devices 42, 44 (i.e., transistors) are shown for illustration purposes. The CMOS devices 42, 44 may control the flow of electrical current between the power source 46 and ground 48.

As was previously mentioned, when the input to the Schmitt trigger 12 is at or near the upper or lower thresholds 30a, 30b of the Schmitt trigger 12, there is a period where the PMOS and NMOS devices 42, 44 are turned on simultaneously. During this period, electrical current, referred to as “shoot-through” current 54, may be conducted from the power supply 46 to ground 48. Because the input is at or near the upper and lower thresholds 30a, 30b a significant portion of the time, the shoot-through current may be a substantial portion of the average oscillator current. Thus, it would be an improvement in the art to reduce the shoot-through current as much as possible, particularly where low power operation is desired.

In selected embodiments in accordance with the invention, a switch 60 (e.g., a transistor 60) may be placed in series with the devices 42, 44 to interrupt and thereby reduce the shoot-through current 54 passing from the power supply 46 to ground 48. In selected embodiments, the switch 60 may be controlled by the output of the Schmitt trigger 12. In this example, when the output of the Schmitt trigger 12 is low, the switch 60 may be turned on, allowing current to flow through the devices 42, 44. Similarly, when the output of the Schmitt trigger is high, the switch 60 may be turned off, interrupting the flow of current 54 through the devices 42, 44. As a result, the input stage 40 may only conduct shoot-through current as Vin approaches the upper threshold, but not after the threshold is reached. In certain embodiments, such a feature may reduce the shoot-through current by substantially half.

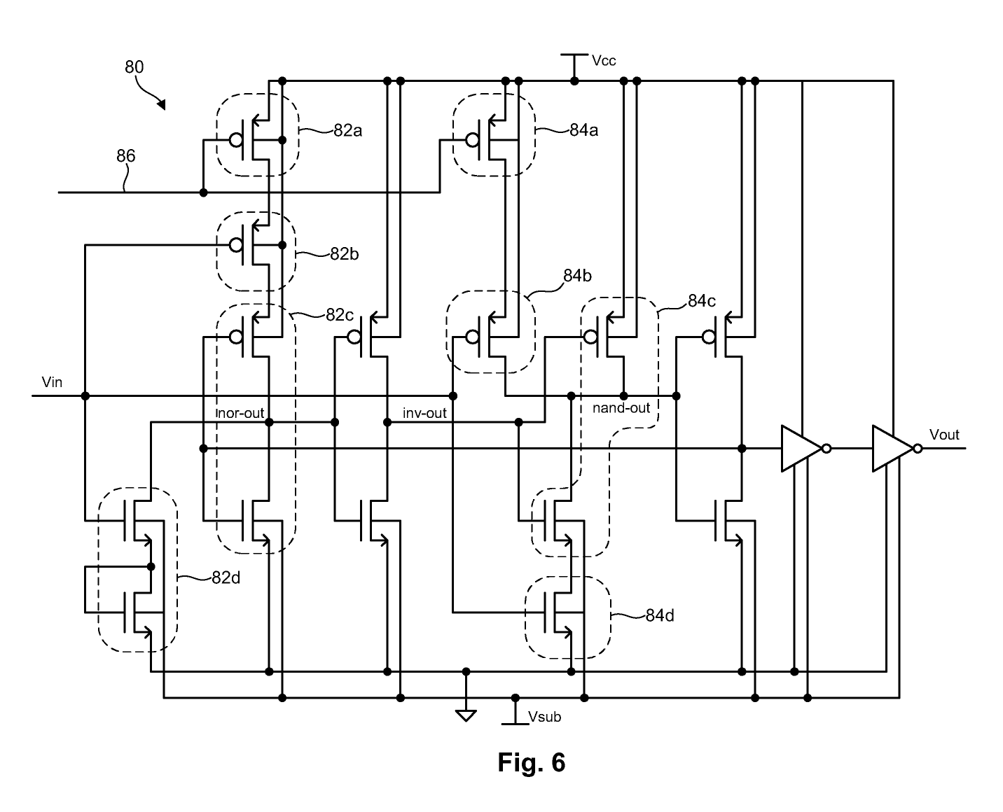

As will be shown in FIG. 6, a Schmitt trigger 12 circuit may include two input stages 40, one for toggling the Schmitt trigger output from high to low, and the other for toggling the Schmitt trigger output from low to high. A switch 60 or switches 60 may be incorporated into each of these input stages to reduce the shoot-through current.

FIGS. 3B and 3C show the shoot-through current 56, in relation to Vin and Vout, both before and after the switch 60 is added to the circuit 10. The dark lines show the shape of the current waveform 56 after the switch 60 is added to the circuit 10. The dotted lines show the shape of the waveform 56 prior to adding the switch 60 to the circuit 10. As shown, the shoot-through current 56 is reduced by substantially half after incorporation of the switch 60.

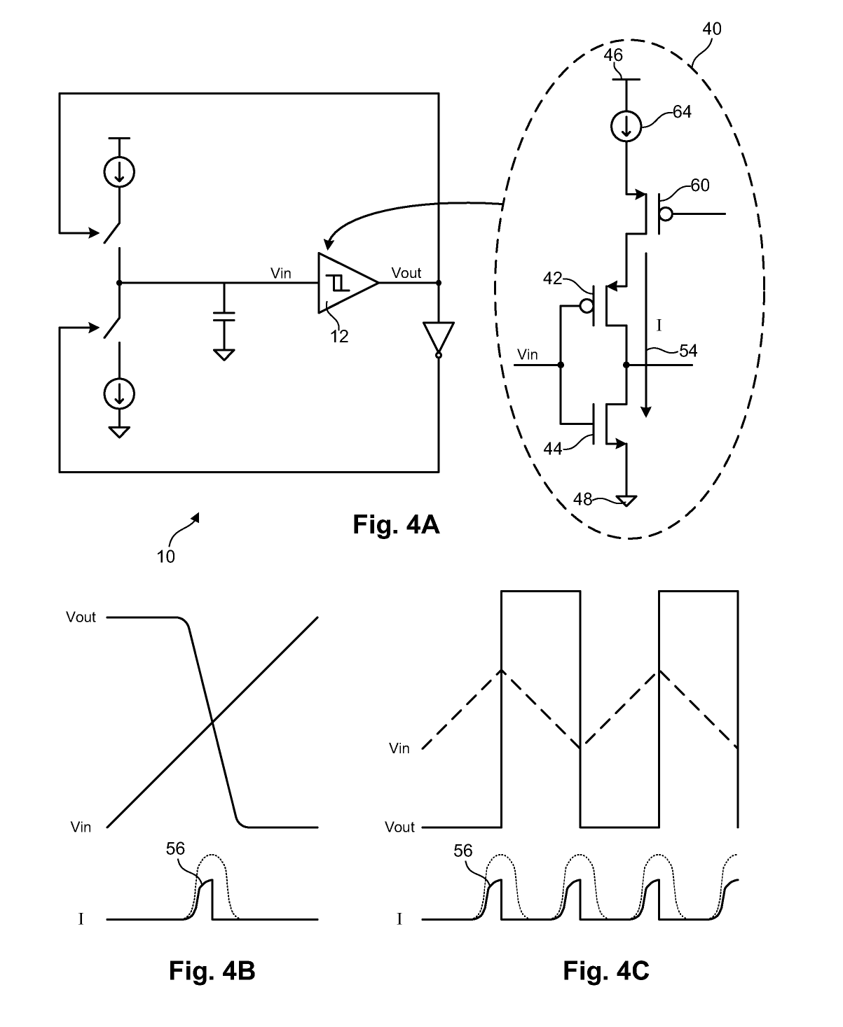

Referring to FIG. 4A, in certain embodiments, a current-limiting device may be added to the circuit 10 to reduce the shoot-through current even further. For example, a current source 64 may be placed in series with the switch 60 and the devices 42, 44 to limit the peak magnitude of the shoot-through current to a desired magnitude. By reducing the shoot-through current by half and limiting the peak magnitude of the shoot-through current, a Schmitt trigger 12 may be constructed that has an average current of less than 1 μA. Furthermore, the average current of the entire oscillator 10 may be less than 2 μA. This represents a significant reduction in power consumption compared to prior art oscillators. Such an oscillator 10 may provide a useful building block in many circuits, particularly circuits where very low power operation is required.

FIGS. 4B and 4C show the shoot-through current 56, in relation to Vin and Vout, both before and after the switch 60 and the current source 64 are added to the circuit 10. The dark lines show the shape of the current waveform 56 after the switch 60 and current source 64 are added to the circuit 10. The dotted lines show the shape of the waveform 56 prior to adding the switch 60 and current source 64 to the circuit 10. As shown, the shoot-through current 56 is reduced even further after the current-limiting device 64 is added to the circuit 10.

In selected embodiments, a Schmitt trigger 12 in accordance with the invention may include the switch 60 to reduce shoot-through current but may omit the current source 64. In other embodiments, the Schmitt trigger 12 may include the current source 64 but may omit the switch 60. In yet other embodiments, the Schmitt trigger 12 may include both the switch 60 and the current source 64 to further minimize the shoot-through current. Each of these embodiments is intended to fall within the scope of the invention.

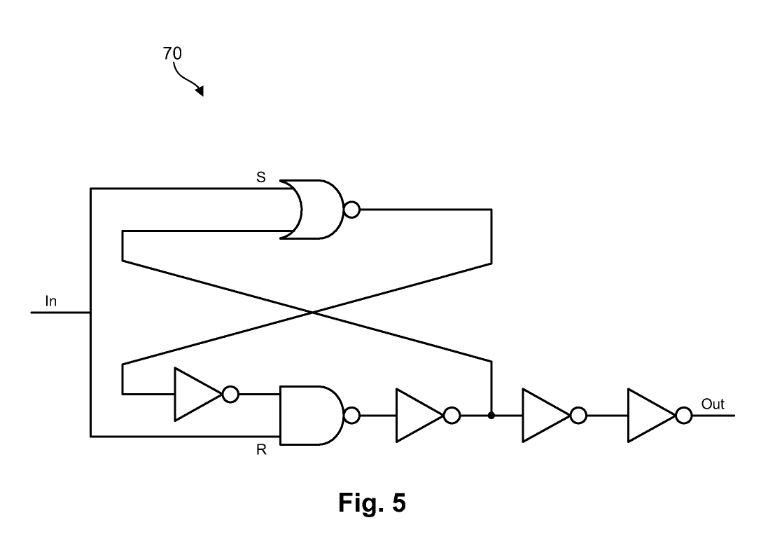

Referring to FIG. 5, in certain embodiments, a Schmitt trigger 12 like that illustrated in FIG. 4A may be constructed using a simple RS latch 70. In this example, the RS latch 70 includes cross-coupled NOR and NAND gates along with several inverters. The S and R inputs are tied together and skewed to have different thresholds to provide hysteresis. The input transitions may be current limited to keep the shoot-through current small for slow input signals. By contrast, internal nodes which have fast transitions may not be current limited.

Referring to FIG. 6, the RS latch described in FIG. 5 may be implemented with transistors using the illustrated circuit 80. To reduce the power that is consumed by the circuit 80, the circuit 80 may include the current-reducing components 60, 64 described in FIGS. 3A and 4A. The illustrated circuit 80 may be implemented with CMOS technology, and more particularly using complementary and symmetrical pairs of PMOS and NMOS field-effect transistors. Nevertheless, the apparatus and methods disclosed herein should not be limited to CMOS technology, but may be applicable to oscillators using other forms of transistor logic susceptible to the shoot-through current previously discussed.

In the illustrated circuit 80, the components 82a-d are included in a first input stage 82. These components 82a-d are responsible for toggling Vout from low to high when Vin reaches the upper threshold voltage. Similarly, the components 84a-d are included in a second input stage 84. These components 84a-d are responsible for toggling Vout from high to low when Vin reaches the lower threshold voltage. All components other than the components 82a-d, 84a-d are simply inverters and buffers. These components and their function are well known to those of skill in the art and thus do not require further explanation.

The devices 82a, 84a are current sources 64 (as described in FIG. 4A) for limiting the peak magnitude of the shoot-through current in each of the input stages 82, 84, respectively. The devices 82a, 84a may be controlled by an input 86. The devices 82b, 82d determine the upper threshold voltage level (i.e., the voltage at which the output will switch from low to high). The devices 84b, 84d determine the lower threshold voltage level (i.e., the voltage at which the output will switch from high to low). The devices 82c are switches 60, controlled by feedback from the output of the Schmitt trigger 12, that are configured to interrupt the shoot-through current when the upper threshold has been reached. Similarly, the devices 84c are switches 60, controlled by feedback from the output of the Schmitt trigger 12, that are configured to interrupt the shoot-through current when the lower threshold has been reached.

The invention may be embodied in other specific forms without departing from its spirit or essential characteristics. The described examples are to be considered in all respects only as illustrative and not restrictive. The scope of the invention is, therefore, indicated by the appended claims rather than by the foregoing description. All changes which come within the meaning and range of equivalency of the claims are to be embraced within their scope.

1. A low power oscillator comprising:
a Schmitt trigger comprising an input, an output, and an input stage coupled to the input, the input stage comprising a plurality of field-effect transistors (FETs) connected in series between a power source and a ground; and
a switch controlled by the output of the Schmitt trigger and connected in series with the plurality of FETs, the switch configured to interrupt shoot-through current passing through the plurality of FETs when the FETs are simultaneously turned on.

2. The low power oscillator of claim 1, further comprising a current source connected in series with the plurality of FETs and configured to limit the magnitude of the shoot-through current.

3. The low power oscillator of claim 1, wherein the plurality of FETs comprises at least one n-channel FET and at least one p-channel FET.

4. The low power oscillator of claim 3, wherein the at least one n-channel FET includes at least one NMOS FET, and the at least one p-channel FET includes at least one PMOS FET.

5. The low power oscillator of claim 1, wherein the operation of the switch reduces the shoot-through current by substantially half.

6. The low power oscillator of claim 1, wherein the switch includes at least one FET.

7. The low power oscillator of claim 1, wherein the switch includes at least one of a PMOS FET and an NMOS FET.

8. The low power oscillator of claim 2, wherein the current source includes at least one FET.

9. The low power oscillator of claim 2, wherein the current source includes at least one of a PMOS FET and an NMOS FET.

10. The low power oscillator of claim 1, wherein the input stage is configured to change a state of the output when a voltage of the input reaches one of a lower threshold voltage and an upper threshold voltage.

11. A method for reducing the power consumed by an oscillator, the method comprising:
providing a Schmitt trigger comprising an input, an output, and an input stage coupled to the input, the input stage comprising a plurality of field-effect transistors (FETs) connected in series between a power source and a ground; and
interrupting, in response to feedback from the output, shoot-through current passing through the plurality of FETs when the FETs are simultaneously turned on.

12. The method of claim 11, further comprising limiting the magnitude of the shoot-through current using a current source.

13. The method of claim 11, wherein the plurality of FETs comprises at least one n-channel FET and at least one p-channel FET.

14. The method of claim 13, wherein the at least one n-channel FET includes at least one NMOS FET, and the at least one p-channel FET includes at least one PMOS FET.

15. The method of claim 11, wherein interrupting the shoot-through current comprises reducing the shoot-through current by substantially half.

16. The method of claim 11, wherein interrupting the shoot-through current comprises using a switch to interrupt the shoot-through current.

17. The method of claim 16, wherein the switch includes at least one FET.

18. The method of claim 12, wherein the current source includes at least one FET.

19. The method of claim 11, wherein the input stage is configured to change a state of the output when a voltage of the input reaches one of a lower threshold voltage and an upper threshold voltage.

20. A low power oscillator comprising:
a Schmitt trigger comprising an input, an output, and an input stage coupled to the input, the input stage comprising a plurality of field-effect transistors (FETs) connected in series between a power source and a ground;
a switch controlled by the output of the Schmitt trigger and connected in series with the plurality of FETs, the switch configured to substantially reduce by half the shoot-through current passing through the plurality of FETs when the FETs are simultaneously turned on; and
a current source connected in series with the plurality of FETs and configured to limit the magnitude of the shoot-through current.
